(19) United States
(12) Patent Application Publication
(10) Pub. No.: US 2011/0126880 A1
(43) Pub. Date: Jun. 2, 2011

(54) Thin-Film Photovoltaic Panel and Method of Producing the Same

(75) Inventors: Yu-Ting Lin, Hsinchu City (TW); Wen-Kai Hsu, Zhubei City (TW); Shih-Che Huang, Chiayi City (TW)

(73) Assignee: Du Pont Apollo Limited, Pak Shek Kok (HK)

(21) Appl. No.: 12/956,770

(22) Filed: Nov. 30, 2010

Related U.S. Application Data
(60) Provisional application No. 61/265,176, filed on Nov. 30, 2009.

(51) Int. Cl. H01L 31/05; H01L 31/18

(52) U.S. Cl. 136/244; 438/73; 257/E31.124

(57) ABSTRACT

A punched metal tape having a conductive strip and an adhesive layer is provided to replace the conventional metal ribbon. The conductive strip surrounding a punched hole can be inversed to the opposite side of the metal tape to directly contact a back metal electrode of a photovoltaic cell.

### RELATED APPLICATIONS

This application claims priority to U.S. Provisional Application Ser. No. 61/265,176, filed Nov. 30, 2009, which is herein incorporated by reference.

### BACKGROUND

1. Technical Field

The disclosure relates to a thin-film photovoltaic panel and a method of producing the same.

2. Description of Related Art

In a conventional method of producing thin-film photovoltaic panel, there are several methods can be used to attach metal ribbons to back metal electrodes of a thin-film photovoltaic panel.

In a first method, the metal ribbons are attached to the back metal electrodes through conductive glue. In the pre-soldering step of this method, the conductive glue has to be first coated on the back metal electrodes as two lines of dots on two opposite sides of the photovoltaic panel. Then, in the wire-bonding step, two metal ribbons are respectively disposed on the two lines of conductive glue dots and attached to the back metal electrodes by high temperature. Therefore, the conductive resistance of the photovoltaic panel and the processed time are determined by the number of the conductive glue dots. The conductive resistance is lower and the processed time is longer when the number of the conductive glue dots is greater. Hence, the production cost is quite high. Still further, in the conventional method for forming the electrode-lead out wiring at the outermost part of the photovoltaic panel, the outermost part of the photovoltaic cell would be damaged while performing the wire-bonding process. This incurs the two strings of the photovoltaic cells not work.

A second method of attaching the metal ribbons to the back metal electrodes is using supersonic welding to decrease the temperature of the wire-bonding. Since the metal ribbons are copper foil plated by tin, supersonic welding can be used to directly attach the metal ribbons to the back metal electrodes in ways of roll welding or spot welding. However, the materials of the back metal electrodes and the metal ribbons have to match each other. Otherwise, the metal ribbons may be peeled from the back metal electrodes. Another problem is the welding time is quite long.

### SUMMARY

According to an embodiment, a photovoltaic panel is provided. The photovoltaic panel comprises a transparent substrate, a plurality of photovoltaic cells, and at least a metal tape. The plurality of photovoltaic cells are parallel arranged on the transparent substrate. Each of the photovoltaic cells comprise a transparent conductive oxide layer, a semiconductor layer, and a back metal electrode. The metal tape, having an adhesive layer and a conductive strip, is on at least one of the back metal electrodes. The adhesive layer is directly on the back metal electrode, and the conductive strip is on the adhesive layer. The conductive strip surrounding the punched hole is inversed to directly contact the back metal electrode.

According to an embodiment, a method for forming electrode-lead out wiring of a photovoltaic panel is provided. A photovoltaic panel having a plurality of photovoltaic cells parallel arranged on a transparent substrate is formed. Each of the photovoltaic cells comprises a transparent conductive oxide layer, a semiconductor layer, and a back metal electrode. Then, at least a metal tape having at least a punched hole is adhered on at least one of the back metal electrodes. The metal tape has an adhesive layer and a conductive strip, wherein the adhesive layer is directly on the back metal electrode, and the conductive strip is on the adhesive layer. The conductive strip surrounding the punched hole is inversed to directly contact the back metal electrode.

Therefore, the above-provided punched metal tape can be easily used to replace the conventional metal ribbon to reach the goals of simpler and faster process and lower cost. Furthermore, no matching problem occurs between the metal tape and the back metal electrode.

### BRIEF DESCRIPTION OF THE DRAWINGS

FIG. 1A is a cross-sectional diagram of a metal tape according to an embodiment.

FIG. 1B is a cross-sectional diagram of the metal tape in FIG. 1 after punching holes.

FIG. 2 is a planar view of a photovoltaic panel.

FIG. 3 is a cross-sectional diagram of the cutting lines 3-3′ in FIG. 2.

FIG. 4 is a cross-sectional diagram of the cutting lines 4-4′ in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

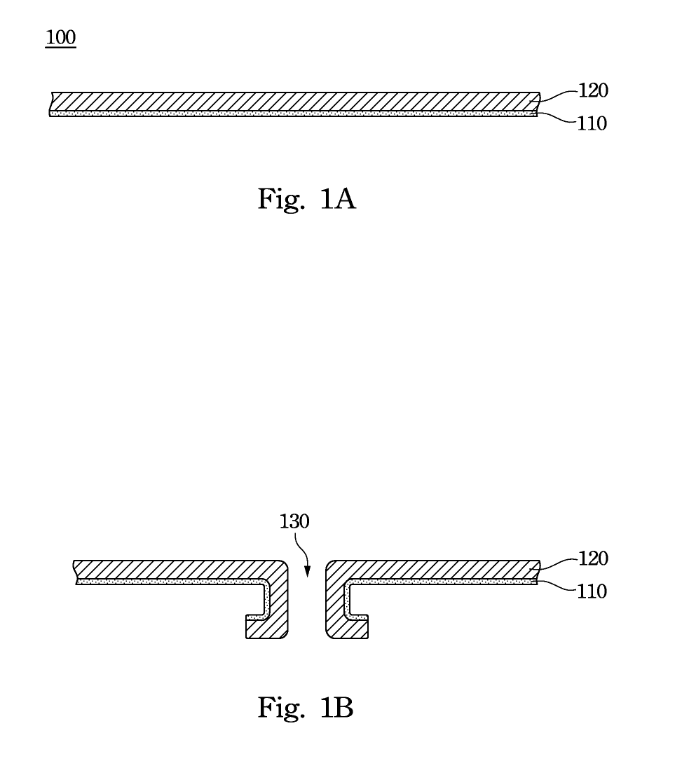

A punched metal tape is provided to replace the metal ribbon in the prior art. FIG. 1A is a cross-sectional diagram of a metal tape according to an embodiment. In FIG. 1A, the metal tape 100 consists of a conductive strip 120 and an adhesive layer 110 coated thereon.

FIG. 1B is a cross-sectional diagram of the metal tape in FIG. 1 after punching holes. In FIG. 1B, the metal tape 100 is punched to form at least one hole 130. The number of the holes defined in the metal tape 100 can be, for example, one to plenty depending on the desired conductivity. Hence, after the hole 130 are created by punching the metal tape 100, the hole 130 cause the punched metal tape 100 to form a collar-like shape extending downward through the metal tape 100, so as to make the punched parts of the metal tape 100 folded over to the opposite side of the metal tape 100.

According to an embodiment, the diameter of the hole 130 is smaller than the distance between two adjacent photovoltaic cells. In detail, if the diameter of the hole 130 is larger than the distance between two adjacent photovoltaic cell, which means that the metal tape 100 with the hole 130 for electrical connections crosses over on the two adjacent photovoltaic cells, and thus short circuit would be caused. Moreover, the diameter of the hole 130 can be 1-10 mm

According to an embodiment, the material of the adhesive layer 110 has good adhesive strength. Moreover, the adhesive layer 110 can be made of nonconductive adhesive materials or conductive adhesive materials. For example, the nonconductive adhesive materials of the adhesive layer 110 can be nonconductive polymer, such as epoxy resin, polycarbonate (PC), polyimide, polyaniline, poly(3,4-ethylenedioxythiophene) (PEDOT), polythiophene, polyethylene terephthalate (PET), or a combination thereof. Alternatively, the conductive adhesive materials of the adhesive layer 110 can be made of the nonconductive polymer above mixed with a metal, such as Ag, Ni, Al, or a combination thereof.

According to an embodiment, the material of the conductive strip 120 has high electrical conductivity. For example, the materials of the conductive strip 120 can be metal, such as Au, Ag, Cu, Fe, Sn, Al, Ti, Mo, or a combination thereof. Alternatively, the materials of the conductive stripe 120 can be non-metal, such as graphite. Alternatively, the materials of the conductive stripe 120 can also be metal oxide, such as ZnO, TiO₂, SnO, or In₂O₃.

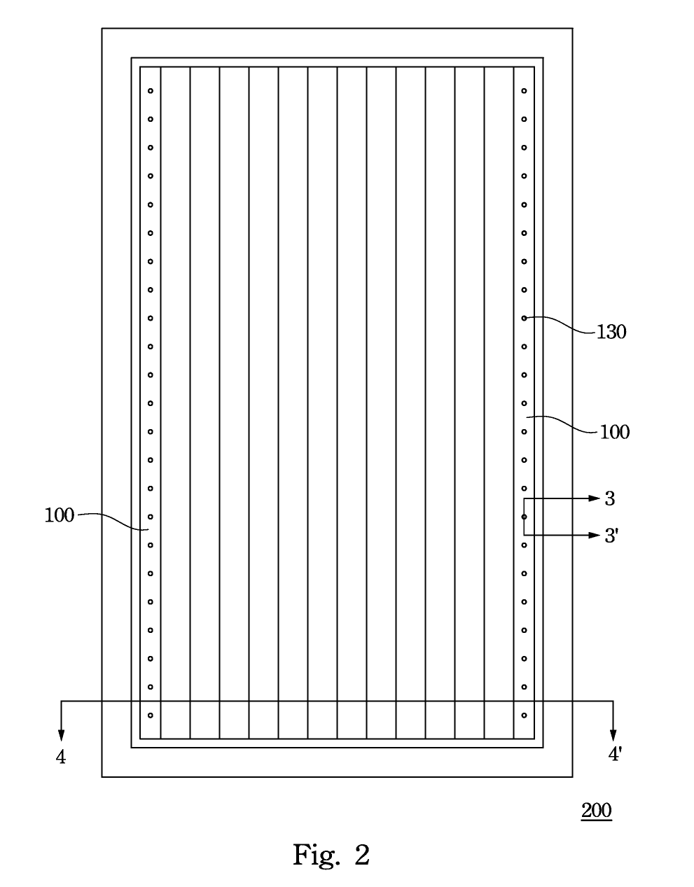

FIG. 2 is a planar view of a photovoltaic panel. The punched metal tape 100 is attached to two opposite sides of the photovoltaic panel 200.

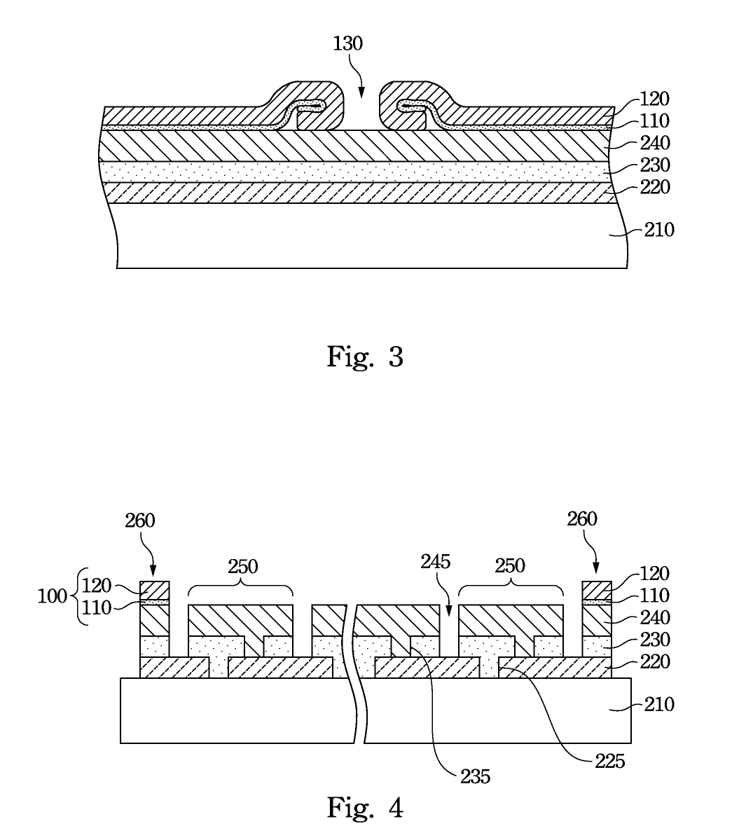

FIG. 3 is a cross-sectional diagram of the cutting lines 3-3′ in FIG. 2. In FIG. 3, the photovoltaic panel 200 sequentially has a transparent substrate 210, a transparent conductive oxide (TCO) layer 220, a semiconductor layer 230, and a back metal electrode 240. The adhesive layer 110 of the punched metal tape 100 is the major part that directly contacts the top surface of the back metal electrode 240. However, as mentioned above, due to the collar-like shape is formed at the punched hole 130, the punched parts of the conductive strip 120 of the metal tape 100 can directly contact the top surface of the back metal electrode 240 to electrically connect the conductive strip 120 to the back metal electrode 240, such that the contact resistance between the metal tape 100 and the back metal electrode 240 can be decreased to well convey the electric current from the photovoltaic panel 200 for its intended purpose. Therefore, the contact resistance is lower when the hole density of the metal tape 100 is higher.

FIG. 4 is a cross-sectional diagram of the cutting lines 4-4′ in FIG. 2. In FIG. 4, the photovoltaic panel 200 sequentially has the transparent substrate 210, the TCO layer 220, the semiconductor layer 230, and the back metal electrode 240. The TCO layer 220 has a first scribed-line 225. The semiconductor layer 230 has a second scribed-line 235. The back metal electrode 240 has a third scribed-line 245. The part between two adjacent third scribed lines 245 is a photovoltaic cell 250.

Moreover, the metal tape 100 directly contacts and attaches onto the back metal electrode 240 on the two opposite outermost part 260 of the photovoltaic cell 250, such that an electrode-lead out wiring, i.e. the metal tape 100, can be easily formed on the back metal electrode 240. Further, since the metal tape 100 above is adhesive and conductive, the metal tape 100 can be directly and easily attached on the back metal electrode 240 of the photovoltaic panel 200 for electrode-lead out wiring without damaging the photovoltaic cell 250 positioned on the outermost part 260. As such, the outermost part 260 of the photovoltaic cell 250 can well work, thereby increasing the total voltage of the photovoltaic panel 200.

Accordingly, the above-provided punched metal tape can be easily used to replace the conventional metal ribbon. The process above for forming the electrode-lead out wiring is simpler and faster. Hence, the production cost is lower. Furthermore, no matching problem occurs between the metal tape and the back metal electrode.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A photovoltaic panel, comprising:
a transparent substrate;
a plurality of photovoltaic cells parallel arranged on the transparent substrate, wherein each of the photovoltaic cells comprises a transparent conductive oxide layer, a semiconductor layer, and a back metal electrode;
at least a metal tape on at least one of the back metal electrodes, wherein the metal tape has at least a punched hole and comprises:
an adhesive layer directly on the back metal electrode; and
a conductive strip on the adhesive layer, wherein the conductive strip surrounding the punched hole is inversed to directly contact the back metal electrode.

2. The photovoltaic panel of claim 1, wherein the punched hole composes a collar-like shape extending through the metal tape.

3. The photovoltaic panel of claim 1, wherein the diameter of the punched hole is smaller than the distance between two adjacent photovoltaic cells.

4. The photovoltaic panel of claim 3, wherein the diameter of the hole is in a range of 1-10 mm.

5. The photovoltaic panel of claim 1, wherein the adhesive layer is made of a non-conductive adhesive material or a conductive adhesive material, and wherein the non-conductive adhesive material is selected from a group consisting of epoxy resin, polycarbonate (PC), polyimide, polyaniline, poly(3,4-ethylenedioxythiophene) (PEDOT), polythiophene, polyethylene terephthalate (PET), and a combination thereof, and wherein the conductive adhesive material comprises at least one of the nonconductive adhesive material above and a metal selected from a group consisting of Ag, Ni, Al, and a combination thereof.

6. The photovoltaic panel of claim 1, wherein the conductive strip is made of a metal, graphite, or a metal oxide, and wherein the metal is selected from a group consisting of Au, Ag, Cu, Fe, Sn, Al, Ti, Mo, and a combination thereof, and the metal oxide is selected from a group consisting of ZnO, TiO₂, SnO, and In₂O₃.

7. A method for forming electrode-lead out wiring of a photovoltaic panel, the method comprising:
forming a photovoltaic panel having a plurality of photovoltaic cells parallel arranged on a transparent substrate, wherein each of the photovoltaic cells comprises a transparent conductive oxide layer, a semiconductor layer, and a back metal electrode; and
adhering at least a metal tape on at least one of the back metal electrodes, wherein the metal tape has at least a punched hole and comprises:
a adhesive layer directly on the back metal electrode; and
a conductive strip on the adhesive layer, wherein the conductive strip surrounding the punched hole is inversed to directly contact the back metal electrode.

8. The method of claim 7, wherein the punched hole composes a collar-like shape extending through the metal tape.

9. The method of claim 7, wherein the diameter of the punched hole is smaller than the distance between two adjacent photovoltaic cells.

10. The method of claim 9, wherein the diameter of the hole is in a range of 1-10 mm.

11. The method of claim 7, wherein the adhesive layer is made of a non-conductive adhesive material or a conductive adhesive material, and wherein the non-conductive adhesive material is selected from a group consisting of epoxy resin, polycarbonate (PC), polyimide, polyaniline, poly(3,4-ethylenedioxythiophene) (PEDOT), polythiophene, polyethylene terephthalate (PET), and a combination thereof, and wherein the conductive adhesive material comprises at least one of the nonconductive adhesive material above and a metal selected from a group consisting of Ag, Ni, Al, and a combination thereof.

12. The method of claim 7, wherein the conductive strip is made of a metal, graphite, or a metal oxide, and wherein the metal is selected from a group consisting of Au, Ag, Cu, Fe, Sn, Al, Ti, Mo, and a combination thereof, and the metal oxide is selected from a group consisting of ZnO, TiO₂, SnO, and In₂O₃.
